(19) United States
(12) Patent Application Publication
(10) Pub. No.: US 2026/0260860 A1
(43) Pub. Date: Sep. 3, 2026

(54) Real Time Radical Output Monitoring Using Optical Emission Spectroscopy

(71) Applicant: MKS Inc., Andover, MA (US)

(72) Inventors: Ilya Pokidov, Winchester, MA (US); Guy Rosenzweig, Andover, MA (US); Robert Hallock, Berlin, MA (US); Mark Roberts, Cape Neddick, ME (US)

(73) Assignee: MKS Inc., Andover, MA (US)

(21) Appl. No.: 19/165,253

(22) PCT Filed: Mar. 19, 2024
(86) PCT No.: PCT/US2024/020561

§ 371 Date: Sep. 15, 2025

Related U.S. Application Data
(60) Provisional application No. 63/453,561, filed on Mar. 21, 2023.

(51) Int. Cl. H01J 37/32; G01N 21/71; H10P 72/00

(52) U.S. Cl. CPC H01J 37/3299; G01N 21/71; H01J 37/32018; H01J 37/32357; H01J 2237/334; H10P 72/0421

(57) ABSTRACT

A system for determining a concentration of radicals within a particle stream to be delivered into a semiconductor processing chamber includes a plasma generator, a spectrometer optically coupled to an glow discharge region of the plasma generator and a controller communicatively coupled to the spectrometer. The plasma source is operative to generate a glow discharge to excite radicals and diluent gas in a received effluent stream. The spectrometer is operative to output measurement data representing an intensity of light emitted by the excited radicals and diluent gas. The controller is operative to calculate a concentration of radicals within the effluent stream based on the measurement data.

### BACKGROUND

Embodiments of the present invention relate generally to an optical emission spectroscopy (OES) radical detection system, and a method for radical detection using optical emission spectroscopy. More specifically, embodiments of the present invention relate to measuring the concentration of radical species in the effluent stream of a remote plasma source used in plasma assisted semiconductor fabrication processes, such as plasma enhanced atomic layer deposition (PEALD), plasma enhanced chemical vapor deposition (PECVD) or plasma etching.

Semiconductor manufacturing processes use plasma sources to generate particles that can be used to facilitate etching and deposition processes, as well as to clean interior surfaces of semiconductor processing chambers. Radicals are often key components within a particle stream as they are extremely reactive due to unpaired electrons. Remote plasma sources are often used to generate radical-containing particle streams at locations remote from semiconductor processing chambers. However, the radicals can be destroyed while being transported to a semiconductor processing chamber. For example, a remote plasma source can generate atomic fluorine radicals by dissociating NF₃ molecules (i.e., NF₃→N+3F), but the fluorine radicals can recombine into molecular fluorine via gas phase and surface reactions (e.g., F+F→F₂). Thus, it can be desirable to measure the concentration of radicals within a particle effluent stream generated by a remote plasma source so that adjustments in the operation of the remote plasma source and/or other components of the semiconductor processing system can be made to correct or compensate for destruction of radicals generated by the remote plasma source.

One known technique for measuring radicals within a particle stream includes calorimetry, which measures the amount of thermal energy released as the result of radicals recombining into stable molecules. This technique is not suitable for use in semiconductor processing because it necessarily results in the destruction (recombination) of the radicals sought to be measured. The same is true of the other known measurement techniques such as etch rate measurement and chemical titration. It is possible to divert a small portion of the effluent stream and apply the aforementioned techniques only to the diverted stream, but the resulting measurements may suffer from poor sensitivity due to the small sample size. In light of the foregoing, there is a need for robust and efficient systems and techniques for detecting radical concentration within a particle stream generated for semiconductor processing.

### SUMMARY

Embodiments of the present invention have been conceived and developed aiming to provide solutions to the above stated objective technical needs, as will be evidenced in the following description.

One embodiment can be generally characterized as a system for determining a concentration of radicals within a particle stream to be delivered into a semiconductor processing chamber, wherein the system includes: a plasma generator having an inlet configured to receive an effluent stream of a particle stream containing radicals and a diluent gas, the plasma source operative to generate a glow discharge to excite the radicals and diluent gas in the received effluent stream; a spectrometer optically coupled to an interior glow discharge region of the plasma generator, wherein the spectrometer is operative to output measurement data representing an intensity of light emitted by the radicals and diluent gas; and a controller communicatively coupled to the spectrometer, the controller operative to calculate a concentration of radicals within the effluent stream based on the measurement data.

Another embodiment can be generally characterized as a particle stream delivery system for use with a semiconductor processing chamber, wherein the system includes: a remote plasma source operative to generate an effluent stream of a particles containing radicals and a diluent gas; a plasma generator having an inlet configured to receive the effluent stream and an outlet configured to be coupled to the semiconductor processing chamber, the plasma source operative to generate a glow discharge to excite the radicals and diluent gas in the effluent stream and convey the effluent stream to the semiconductor processing chamber; a light blocking feature arranged between the remote plasma source and the plasma generator, wherein the light blocking feature is configured to convey the effluent stream but prevent light emitted by the remote plasma source from reaching the plasma generator; a spectrometer optically coupled to an interior glow discharge region of the plasma source, wherein the spectrometer is operative to output measurement data representing an intensity of light emitted by the radicals and diluent gas; and a controller communicatively coupled to the spectrometer, the controller operative to calculate a concentration of radicals within the effluent stream based on the measurement data.

### BRIEF DESCRIPTION OF DRAWINGS

The above and other aspects, features and advantages of the present invention will become more apparent from the subsequent description thereof, presented in conjunction with the following drawings, wherein:

FIGS. 1 and 2 are schematically views illustrating OES radical detection systems according to some embodiments of the present invention.

FIG. 3 is a schematic view illustrating certain components of the OES radical detection systems shown in FIGS. 1 and 2.

FIG. 4 is a schematic view illustrating one embodiment of the spectrometer shown in FIGS. 1 and 2.

FIG. 5 is a chart comparing results of the radical concentration determination technique according to embodiments of the present invention, as measured at various pressures, with measured etch rates as a function of pressure.

### DETAILED DESCRIPTION OF THE INVENTION

Exemplary embodiments are described below with reference to the accompanying drawings. Unless otherwise expressly stated, in the drawings the sizes, positions, etc., of components, features, elements, etc., as well as any distances therebetween, are not necessarily to scale, and may be disproportionate and/or exaggerated for clarity.

The terminology used herein is for the purpose of describing particular example embodiments only and is not intended to be limiting. As used herein, the singular forms “a,” “an” and “the” are intended to include the plural forms as well, unless the context clearly indicates otherwise. It should be recognized that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Unless otherwise specified, a range of values, when recited, includes both the upper and lower limits of the range, as well as any sub-ranges therebetween. Unless indicated otherwise, terms such as “first,” “second,” etc., are only used to distinguish one element from another. For example, one node could be termed a “first mirror” and similarly, another node could be termed a “second mirror”, or vice versa.

Unless indicated otherwise, the term “about,” “thereabout,” etc., means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those skilled in the art.

Many of the embodiments described in the following description share common components, devices, and/or elements. Like named components and elements refer to like named elements throughout. For example, many of the embodiments described in the following detailed description include at least one ultrapure water source (hereinafter UPW source), carrier gas source, ammonia gas source, main flow pathway, bypass flow pathway, and the like. Thus, the same or similar named components or features may be described with reference to other drawings even if they are neither mentioned nor described in the corresponding drawing. Also, even elements that are not denoted by reference numbers may be described with reference to other drawings.

Many different forms and embodiments are possible without deviating from the spirit and teachings of this disclosure and so this disclosure should not be construed as limited to the example embodiments set forth herein. Rather, these example embodiments are provided so that this disclosure will be thorough and complete, and will convey the scope of the disclosure to those skilled in the art.

Remote plasma sources (RPSs) are used to generate excited free radicals, such as F, O, H, N, etc., which are used in semiconductor processing. A non-invasive, in-situ method of measuring radical density in the effluent stream of an RPS can be used to monitor semiconductor processes, such as deposition or etch and ultimately, provide real time feedback to the RPS for closed loop process control. To overcome limitations associated with conventional techniques for measuring radical yields of RPSs as discussed above, embodiments of the present invention employ the use of optical emission spectroscopy (OES), and more specifically optical actinometry, for measuring radical concentration in the effluent stream of an RPS.

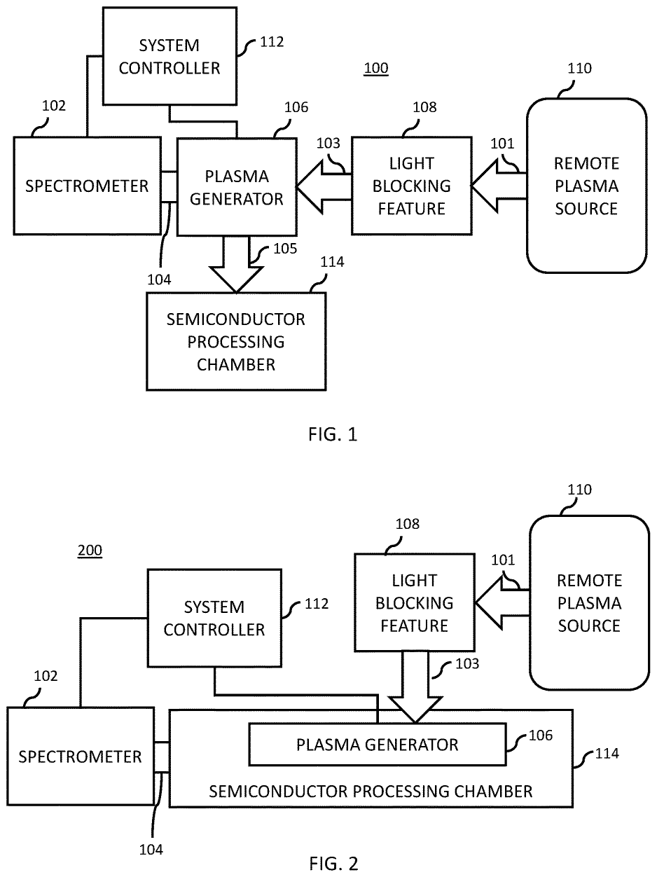

Exemplary configurations of an OES radical detection system (i.e., an OES actinometry system) according to embodiments of the present invention are shown schematically in FIGS. 1 and 2. Generally, the OES actinometry system 100 shown in FIG. 1 and the OES actinometry system 200 shown in FIG. 2 can be characterized as including a spectrometer 102 optically coupled to a plasma generator 106 (e.g., via a view port 104), a light blocking feature 108, and a system controller 112. Also shown in FIGS. 1 and 2, is an RPS 110 and a semiconductor processing chamber 114.

Although not shown, the RPS 110 may be fluidically connected to one or more precursor sources containing a composition from which a plasma containing one or more radicals (e.g., F, O, H, N, etc.) is to be formed, as is known in the art. Also, and although not shown, the RPS 110 may be fluidically connected to one or more sources of a diluent gas (e.g., Ar, He, N₂, etc.) used, for example, to aid in transport of the radicals within the effluent stream, as is known in the art. Although only one RPS 110 and one OES actinometry system are shown in FIGS. 1 and 2, it will be appreciated that multiple RPSs 110 may be provided and be fluidically connected to the same OES actinometry system 100 or 200 (e.g., at the light blocking feature 108).

The light blocking feature 108 is coupled to the output of the RPS 110 (e.g., by one or more pipes, conduits, etc.) to receive the radicals and diluent gas in the effluent stream generated by the RPS 110 (e.g., as indicated by 101). The light blocking feature 108 is configured to allow the radicals and diluent gas within the effluent stream to pass therethrough (e.g., as indicated by 103) while absorbing, attenuating, intercepting or otherwise blocking light emitted from the plasma generated inside the RPS 110. By blocking light emissions from the RPS 110, the light blocking feature 108 prevents a line of sight between output of the RPS 110 and the spectrometer 102 and helps to minimize interference with an optical signal used to measure the radical concentration in the effluent stream of the RPS 110.

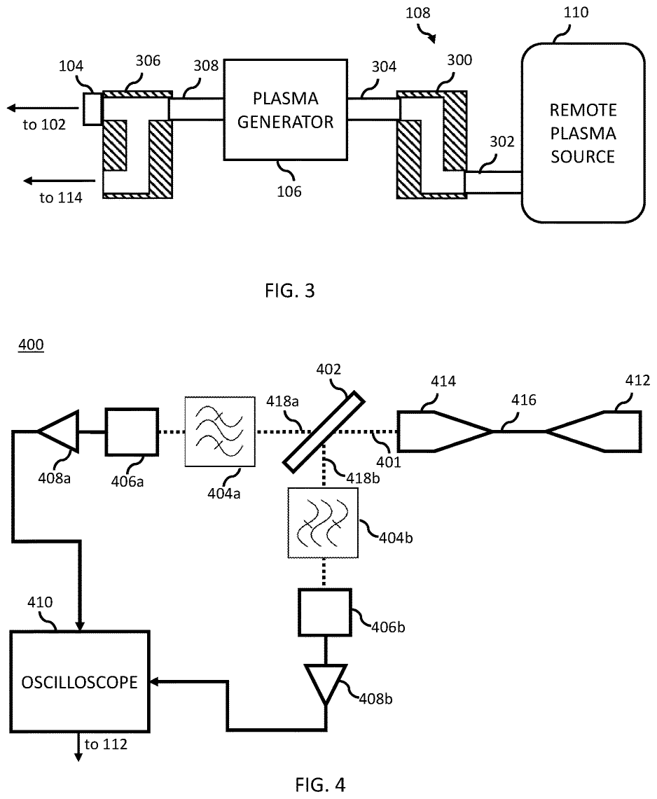

Examples of light blocking features 108 include, but are not limited to, a bend, a baffle, a screen, or the like or any combination thereof. For example, the light blocking feature 108 can be provided as bend 300 shown in FIG. 3. The bend 300 may, for example, be provided as a block or body defining a channel extending therethrough. In the illustrated embodiment, the channel has two bends, e.g., at 90 degrees, but each bend may be at any suitable angle. While the channel is illustrated as having two bends, it will be appreciated that the channel may have a single bend, or more than two bends. In the example embodiment shown in FIG. 3, the channel of the bend 300 is fluidically coupled to the output of the RPS 110 by a conduit 302. Accordingly, radicals in the effluent stream generated by the RPS 110 can be conveyed through the conduit 302 to the double-bend block 300.

Referring back to FIGS. 1 and 2, an inlet of the plasma generator 106 is fluidically coupled to the light blocking feature 108 (e.g., by one or more pipes, conduits, etc.) to receive the effluent stream passed therethrough (e.g., as indicated at 103). The plasma generator 106 is operative to generate a glow discharge (e.g., within a glow discharge region thereof), thereby exciting radicals and diluent gas in the received effluent stream so that they emit light. In particular, the plasma generator 106 is configured to excite the radicals and diluent gas such that they emit photons and generate an optical signal sufficiently strong to be detected by the spectrometer 102. It should be appreciated, however, that the excitation should not be so great as to chemically alter (e.g., dissociate, recombine, react, etc.) constituents (including the radicals) within the effluent stream (or should not chemically alter the effluent stream constituents in a manner that undesirably affects processing to be performed in the semiconductor processing chamber 114). Therefore, the power of the plasma generator 106 can be relatively low (e.g., between several milliwatts and tens of watts). The plasma generator 106 can be provided as a capacitively coupled (CCP), an inductively coupled (ICP), a pulsed DC plasma source, a microwave plasma source, or the like.

In the example embodiment shown in FIG. 3, the input of the plasma generator 106 is coupled to the channel of the bend 300 by conduit 304. Accordingly, the radicals and diluent gas in the effluent stream generated by the RPS 110 can be conveyed from the bend 300 to the plasma generator 106 through the conduit 304.

Referring back to FIGS. 1 and 2, the plasma generator 106 is further configured to allow the radicals and diluent gas within the effluent stream to pass therethrough (e.g., for subsequent distribution into the semiconductor processing chamber 114). In one embodiment, the plasma generator 106 may be provided as the CLEANLINE, model KF40, foreline plasma clean system manufactured by MKS INSTRUMENTS, INC. For example, in the embodiment shown in FIG. 1, the plasma generator 106 is located outside the semiconductor processing chamber 114 and an outlet of the plasma generator 106 can be fluidically coupled to the semiconductor processing chamber 114 (e.g., by one or more pipes, conduits, etc., as known in the art) so that gas within the effluent stream can be passed from the plasma generator 106 into the interior of the semiconductor processing chamber 114 (e.g., as indicated by 105).

Referring to the example embodiment shown in FIG. 3, a branching block 306 may be provided to fluidically couple the output of the plasma generator 106 (arranged as shown in FIG. 1) to the semiconductor processing chamber 114 and to transmit light emitted from the excited radicals to the viewport 104. In this case, a first end of a channel in the branching block 306 is coupled to a conduit 308 (which, in turn, is coupled to the output of the plasma generator 106), a second end of the channel of the branching block 306 is coupled to the viewport 104, and a third end of the channel of the branching block 306 is coupled to the semiconductor processing chamber 114 (e.g., via one or more pipes, conduits, etc.). Accordingly, radicals and diluent gas in the effluent stream generated by the RPS 110 (which have been excited by the plasma generator 106) can be conveyed through the conduit 308 and branching block 306 to the semiconductor processing chamber 114 while light transmitted to the viewport 104 can be transmitted to the spectrometer 102. While the embodiment illustrated in FIG. 3 uses the same branching block 306 to convey radicals in the effluent stream generated by the RPS 110 to the semiconductor processing chamber 114 and to transmit light emitted by the radicals and diluent gas (excited by the plasma generator 106) to the viewport 104, it will be appreciated that other devices may be used for similar purposes. For example, viewport 104 may be provided at an appropriate location directly on the plasma generator 106 and a pipe or conduit may be coupled at a different location to an output of the plasma generator 106 where the effluent can be transmitted.

In the embodiment shown in FIG. 2, the plasma generator 106 is arranged within the semiconductor processing chamber 114 (e.g., which may be provided as a chamber in which one or more processes such as plasma enhanced chemical vapor deposition (PECVD), plasma enhanced atomic layer deposition (PEALD), and etch, or the like or any combination thereof) can be performed.

Referring to FIGS. 1 and 2, the viewport 104 provides a line of sight view into the plasma generated by the plasma generator 106, thereby enabling the spectrometer to be optically coupled to the plasma generator 106. In the embodiment shown in FIG. 1, the viewport 104 is provided on the plasma generator 106 and an optical input of the spectrometer 102 is mounted to the viewport 104. In the embodiment shown in FIG. 2, the viewport 104 is provided on the semiconductor processing chamber 114 (at a location where light from the radicals excited by plasma generator 106 can be seen) and the optical input of the spectrometer 102 is mounted to the viewport 104. In another embodiment, however, the spectrometer 102 can be located remote from the viewport 104, and one or more optical fibers or other waveguides can be used to transmit light from the viewport 104 to the spectrometer 102. Regardless of the manner in which the spectrometer 102 is optically coupled to the plasma generator 106, a first optical element (e.g., a light collection element, not shown) can be provided at the viewport 104 to focus the light and thereby increase the amount of light generated from the radicals excited by plasma generator 106 to be transmitted into the spectrometer 102 as an optical signal. A second optical element (e.g., a collimator, not shown) can also be provided to collimate the light transmitted from the first optical element so that the light entering the spectrometer 102 is a collimated optical signal.

The spectrometer 102 is operative to measure light emitted by the radicals and diluent gas (upon excitation by the plasma generator 106) and generate measurement data based on the measured light. In some embodiments, the spectrometer 102 is configured to measure an optical signal within a continuous wavelength range, for example from 200 nm to 1100 nm, from 650 nm to 840 nm, etc. In other embodiments, the spectrometer 102 is configured to measure an optical signal at one or more discrete wavelengths, or within a plurality of relatively narrow wavelength ranges. For example, the spectrometer 102 may be provided as an OPTOFLASH spectrometer engine manufactured by NEWPORT CORPORATION. Example embodiments of a discrete wavelength (or narrow linewidth) spectrometer that may be used as the spectrometer 102 are described in greater detail in U.S. Pat. No. 8,633,440, which is incorporated herein by reference. In some cases, use of discrete wavelength (or narrow linewidth) spectrometers can be advantageous over continuous wavelength spectrometers due to their relatively low cost, small size, and faster data collection/processing speed. An example embodiment of a discrete wavelength spectrometer that can be used as spectrometer 102 is described in greater detail with respect to FIG. 4.

Referring to FIG. 4, the discrete wavelength spectrometer 400 (also referred to herein simply as “spectrometer 400”) can include a beam splitter 402 (e.g., a dichroic beam splitter), a first bandpass filter 404a, a second bandpass filter 404b, a first photodiode 406a, a second photodiode 406b, a first amplifier 408a, a second amplifier 408b and an oscilloscope 410. Also shown in FIG. 4 are the aforementioned light collection element (identified at 412), collimator (identified at 414) and an optical fiber 416 optically coupling the light collection element 412 and collimator 414. In another embodiment however the optical fiber 416 may be omitted, in which case the light collection element 412 and collimator 414 are provided as a single component that performs the functions of both the light collection element 412 and collimator 414.

The beam splitter 402 is used to split an incoming optical signal propagating along an input beam path 401 into a first optical signal (e.g., having one or more wavelengths within a transmission band of the beam splitter 402, and which is propagatable along a first beam path 418a, shown in FIG. 4 as a dotted line) and a second optical (e.g., having one or more wavelengths within a reflection band of the beam splitter 402, and which is propagatable along a second beam path 418b, shown in FIG. 4 as a dotted line). Wavelengths in the transmission band of the beam splitter 402 may be higher or lower than wavelengths in the reflection band thereof. The transition wavelength between the transmission band and reflection band of the beam splitter 402 may be tuned or otherwise selected based on the type(s) of radicals and diluent gas present in the effluent stream generated by the RPS 110. For example, if the RPS 110 generates an effluent stream containing fluorine (F) radicals in an argon (Ar) diluent gas, then the transition wavelength can be, for example, 725 nm (or thereabout). Accordingly, any light within the first optical signal transmitted along first beam path 418a by the beam splitter 402 will have one or more wavelengths above 725 nm (or thereabout) and any light within the second optical signal reflected along second beam path 418b by the beam splitter 402 will have one or more wavelengths below 725 nm (or thereabout).

The first bandpass filter 404a is positioned within the first beam path 418a and is configured to transmit only a portion of the spectrum within the first optical signal propagating along the first optical path 418a, thereby producing a first filtered optical signal. Likewise, the second bandpass filter 404b is positioned within the second beam path 418b and is configured to transmit only a portion of the spectrum within the second optical signal propagating along the second optical path 418b, thereby producing a second filtered optical signal. Each of the first bandpass filter 404a and the second bandpass filter 404b can have a passband center wavelength that is tuned or otherwise selected based on the type(s) of radicals present in the effluent stream generated by the RPS 110. For example, if the RPS 110 generates an effluent stream containing fluorine (F) radicals in the argon (Ar) diluent gas, then the first bandpass filter 404a can have a first passband center wavelength in a range from 750 nm (or thereabout) to 751 nm (or thereabout), for example, 750.4 nm (or thereabout), and the second bandpass filter 404b can have a second passband center wavelength in a range from 703 nm (or thereabout) to 704 nm (or thereabout), for example, 703.7 nm (or thereabout). Each of the first bandpass filter 404a and the second bandpass filter 404b may have a bandwidth (FWHM) of 7 nm, 5 nm, 4 nm, 3 nm, 2 nm, 1 nm, or the like or between any of these values.

The first photodiode 406a is positioned within the first beam path 418a, optically downstream of the first bandpass filter 404a, and the second photodiode 406b is positioned within the second beam path 418b at a location optically downstream of the second bandpass filter 404b. The first photodiode 406a is operative to produce an electric current in response to light within the first filtered optical signal and incident thereto. Likewise, the second photodiode 406b is operative to produce an electric current in response to light within the second filtered optical signal and incident thereto. Generally, the configuration of the first photodiode 406a and the second photodiode 406b will depend upon the wavelength(s) of light emitted by the radicals in the effluent stream of the RPS 110 and excited by the plasma generator 106. If the excited radicals emit light in the visible range of the electromagnetic spectrum (e.g., between 400 nm and 1100 nm), then the first photodiode 406a and the second photodiode 406b can each be provided as a silicon photodiode. It should be recognized that other types of devices may be used convert the light transmitted by a bandpass filter into an electrical signal. For example, a photomultiplier tube may be used instead of a photodiode.

The electric current produced by the first photodiode 406a and the second photodiode 406b can be generally regarded as proportional to the intensity of the light incident thereto. Due to the relatively low amount of light that often reaches the first photodiode 406a and the second photodiode 406b, an amplifier is used to amplify and convert the electric current output therefrom into a voltage signal (i.e., representing the intensity of light incident upon each respective photodiode), which can be measured by the oscilloscope 410. Accordingly, the first amplifier 408a is electrically connected to the output of the first photodiode 406a and the second amplifier 408b is electrically connected to the output of the second photodiode 406b. Each of the first amplifier 408a and the second amplifier 408b can be provided as a transimpedance amplifier. The outputs of the first amplifier 408a and the second amplifier 408b are each connected to an electrical input of the oscilloscope 410.

The oscilloscope 410 is operative to measure the voltage signals output by the first amplifier 408a and the second amplifier 408b to generate and output therefrom measurement data representative of the measured voltage signals. For example, measurement data output by the oscilloscope 410 may represent a first voltage level of the first voltage signal output by the first amplifier 408a (which corresponds to the intensity of light emitted by the diluent gas in the effluent stream, as excited by the plasma generator 106) and a second voltage level of the second voltage signal output by the second amplifier 408b (which corresponds to the intensity of light emitted by radicals in the effluent stream, as excited by the plasma generator 106).

Although not shown in FIG. 4, an enclosure may be provided to surround optical components such as the beam splitter 402, first bandpass filter 404a, second bandpass filter 404b, first photodiode 406a and second photodiode 406b to at least substantially prevent ambient light interfering with the operation of the optical components of the spectrometer 400. The collimator 414 may be a part of the spectrometer 400 (e.g., arranged within the enclosure) or may be detachably coupled to an exterior of the enclosure (e.g., at a location of the enclosure defining an optical input port of the spectrometer 400).

Constructed as exemplarily described above, the spectrometer 400 is configured to simultaneously measure two channels corresponding to two different wavelength bands (i.e., a first filtered optical signal within a first wavelength band corresponding to the first bandpass filter 404a and a second filtered optical signal within a second wavelength band corresponding to the second bandpass filter 404b), and generate corresponding measurement data. It will be appreciated that other embodiments of the spectrometer 400 can be configured to generate measurement data corresponding to filtered optical signals in two or more wavelength bands. For example, the spectrometer 102 can be provided as described in aforementioned U.S. Pat. No. 8,633,440, which is incorporated herein by reference. Accordingly, the spectrometer 400 can be configured to generate measurement data corresponding to the intensity of one or more radicals present in the effluent stream generated by the remote plasma generator 110.

Although he spectrometer 400 has been described above as using a beam splitter 402 provided as a reflective dichroic element, it will be appreciated that the beam splitter 402 may be provided as one or more mirrors, 50:50 beamsplitters, reflective dichroic elements, or the like or any combination thereof, to split or steer an incident optical signal into separate optical signals propagating, ultimately, to separate bandpass filters and/or photodiodes. Further, although the spectrometer 400 has been described above as using the beam splitter 402 and associated bandpass filters 404a and 404b to simultaneously produce filtered optical signals, other devices may be used to produce filtered optical signals from which measurement data can be generated. For example, a filter assembly (e.g., a filter wheel) having a plurality of passband filters (each having different passband center wavelengths) mounted to a motorized and movable frame may be used to generate a series of filtered optical signals. In this case, the frame may be repeatedly actuated to selectively position different filters mounted thereto in the input beam path 401 to produce a series of filtered optical signals, which then would propagate to a photodiode as discussed above.

Referring back to FIGS. 1 and 2, the system controller 112 can be communicatively coupled to the spectrometer 102 and the plasma generator 106 to control their operation. For example, if the spectrometer 102 is provided with a filter assembly as described above, then actuation of the filter assembly (e.g., to control which filter is arranged in the beam path at any time) may be controlled to measure a filtered optical signal associated with a corresponding radical. The system controller 112 may control one or more parameters associated with operation of the plasma generator 106, such as applied power level, timing of operation, etc.

Optionally, the system controller 112 may also be communicatively coupled to the remote plasma source 110 to control an operation thereof so that a concentration of radicals output by the remote plasma source 110 can be adjusted. For example, the system controller 112 may be configured to generate one or more commands which, when transmitted to the RPS 110 (or a controller associated therewith) are effective for controlling the operation of the RPS 110.

The system controller 112 is also operative to receive the measurement data (e.g., conveyed as one or more signals output from the spectrometer 102) and, as will be described in greater detail below, process the measurement data to calculate the radical concentration in the effluent stream of the RPS 110. In one embodiment, the system controller 112 may generate one or more commands to be output to the RPS 110 to control the operation of the RPS 110, e.g., based on the calculated radical concentration in the effluent stream generated by the RPS 110.

Generally, the system controller 112 can be communicatively coupled to the plasma generator 106 and/or the spectrometer 102 over one or more wired or wireless, serial or parallel, communications links (e.g., USB, RS-232, Ethernet, Firewire, Wi-Fi, RFID, NFC, Bluetooth, Li-Fi, SERCOS, MARCO, EtherCAT, or the like or any combination thereof). The system controller 112 includes one or more processors operative to generate the aforementioned control signals upon executing instructions. A processor can be provided as a programmable processor (e.g., including one or more general purpose computer processors, microprocessors, digital signal processors, or any other suitable form of circuitry including programmable logic devices (PLDs), field-programmable gate arrays (FPGAs), field-programmable object arrays (FPOAs), application-specific integrated circuits (ASICs)—including digital, analog and mixed analog/digital circuitry- or the like, or any combination thereof) operative to execute the instructions. Execution of instructions can be performed on one processor, distributed among processors, made parallel across processors within a device or across a network of devices, or the like or any combination thereof.

In one embodiment, the system controller 112 includes tangible media such as computer memory, which is accessible (e.g., via one or more wired or wireless communications links) by the processor. As used herein, computer memory (or, more simply, “memory”) includes magnetic media (e.g., magnetic tape, hard disk drive, etc.), optical discs, volatile or non-volatile semiconductor memory (e.g., RAM, ROM, NAND-type flash memory, NOR-type flash memory, SONOS memory, etc.), etc., and may be accessed locally, remotely (e.g., across a network), or a combination thereof. Generally, the instructions may be stored as computer software (e.g., executable code, files, instructions, etc., library files, etc.), which can be readily authored by artisans, from the descriptions provided herein, e.g., written in C, C++, Visual Basic, Java, Python, Tel, Perl, Scheme, Ruby, assembly language, hardware description language (e.g., VHDL, VERILOG, etc.), etc. Computer software is commonly stored in one or more data structures conveyed by computer memory.

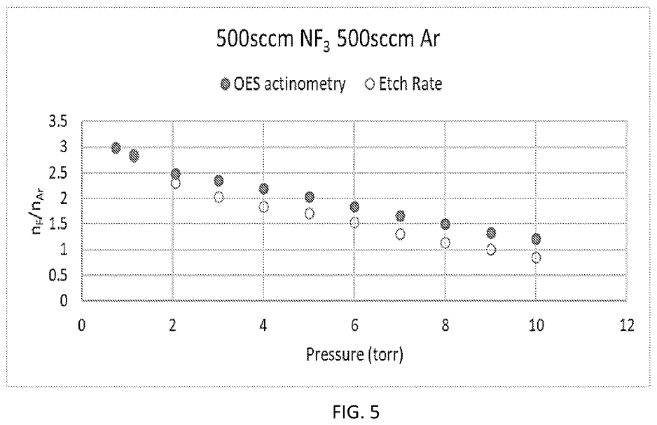

As mentioned above, the system controller 112 is operative to process the measurement data output by the spectrometer 102 to calculate the concentration of radicals in the effluent stream of the RPS 110. In one embodiment, the system controller 112 is operative to calculate the concentration of a radical species in the effluent stream of the RPS 110 according to the following equation:

$$\frac{{n}_{R}}{{n}_{D}} = {C}_{AT} \frac{{V}_{R}}{{V}_{D}}$$

where n_{R} is the number density of radicals (R) present in the effluent stream output by the RPS 110 to be measured, n_{D} is the number density of atoms of diluent gas (D) present in the effluent stream output by the RPS 110, V_{R} is the aforementioned second voltage level (i.e., corresponding to the intensity of light emitted by radicals in the effluent stream, as excited by the plasma generator 106), V_{D} is the aforementioned first voltage level (i.e., corresponding to the intensity of light emitted by the diluent gas in the effluent stream, as excited by the plasma generator 106), and C_{AT} is an empirically-determined proportionality constant associated with the radical concentration to be measured. For example, it is known that the recombination of radicals is known to increase with pressure; therefore, the amount of radicals within an effluent stream can be expected to decrease with increasing pressure. If radicals within the effluent stream to be measured are used to facilitate an etching or deposition process, then the C_{AT} may correspond to a predetermined etch rate or deposition rate. For example, and with reference to FIG. 5, if the RPS 110 fed with 500 sccm NF₃ and 500 sccm Ar generates an effluent stream containing F radicals in an Ar diluent gas, then C_{AT} may represent the etch rate of SiO₂ by F radicals. As shown in FIG. 5, concentration of fluorine radicals (i.e., R=F) within the effluent stream also containing Ar as a diluent gas (i.e., D=Ar), calculated using the systems and techniques of the embodiments described herein at various pressures, is calculated to decrease with increasing pressure. This decrease in radical concentration is fairly consistent with the decrease in SiO₂ etch rate by F radicals as a function of pressure. Thus, the OES actinometry systems and radical concentration techniques exemplarily described herein can be regarded as providing suitably accurate results.

In view of the above, an exemplary procedure for measuring radical concentration in the effluent stream generated by the RPS 110, using the OES actinometry systems and techniques described herein, can begin with causing a diluent gas to flow to the RPS 110, setting diluent gas flow rate and pressure and waiting for the diluent gas flow and pressure to stabilize. Then, operate the RPS 110 to generate a plasma and wait for the diluent plasma to become stable. Next, the radical precursor (e.g., NF₃ gas) can be permitted to flow to the RPS 110, and thereafter set the precursor gas flow rate and wait for the precursor gas flow and pressure to stabilize. Next, the plasma generator 106 is operated to generate a plasma downstream from the RPS 110. The downstream plasma is allowed to stabilize and, at this point, light emitted by the radicals and diluent gas in the effluent stream by the glow discharge of the plasma generator 106 is collected and propagated to the spectrometer 102. The spectrometer 102 generates the measurement data as discussed above, and the measurement data is transmitted to the system controller 112 and the system controller 112 calculates the radical concentration within the effluent stream.

The foregoing is illustrative of embodiments and examples of the invention and is not to be construed as limiting thereof. Although a few specific embodiments and examples have been described with reference to the drawings, those skilled in the art will readily appreciate that many modifications to the disclosed embodiments and examples, as well as other embodiments, are possible without materially departing from the novel teachings and advantages of the invention. Accordingly, all such modifications are intended to be included within the scope of the invention as defined in the claims. For example, skilled persons will appreciate that the subject matter of any sentence, paragraph, example or embodiment can be combined with subject matter of some or all of the other sentences, paragraphs, examples or embodiments, except where such combinations are mutually exclusive. The scope of the present invention should, therefore, be determined by the following claims, with equivalents of the claims to be included therein.

1. A system for determining a concentration of radicals within a plasma-generated particle stream to be delivered into a semiconductor processing chamber, the system comprising:
a plasma generator having an inlet configured to receive an effluent stream of a particle stream containing radicals and a diluent gas, the plasma source operative to generate a glow discharge to excite the radicals and diluent gas in the received effluent stream;
a spectrometer optically coupled to an interior glow discharge region of the plasma generator, wherein the spectrometer is operative to output measurement data representing an intensity of light emitted by the radicals and diluent gas; and
a controller communicatively coupled to the spectrometer, the controller operative to calculate a concentration of radicals within the effluent stream based on the measurement data.

2. The system of claim 1, wherein the plasma generator is external operable outside the semiconductor processing chamber.

3. The system of claim 1, wherein the plasma generator is an in-situ plasma generator operable within the semiconductor processing chamber.

4. The system of claim 1, wherein the spectrometer is a continuous wavelength spectrometer.

5. The system of claim 1, wherein the spectrometer is a discrete wavelength spectrometer.

6. The system of claim 1, wherein the controller is operative to generate one or more commands effective for controlling an operation of a source of the particle stream.

7. The system of claim 1, further comprising a light blocking feature coupled to the inlet of the plasma source, wherein the light blocking feature is configured to convey the effluent stream but prevent light emitted by the remote plasma source from reaching the plasma generator.

8. The system of claim 7, wherein the light blocking feature includes at least one selected from the group consisting of a bend, a baffle and a screen.

9. The system of claim 1, further comprising a viewport coupled to the plasma source, wherein the viewport is configured to transmit light emitted by the excited radicals and diluent gas in the received effluent stream.

10. The system of claim 1, further comprising a remote plasma source fluidically coupled to the inlet of the plasma generator, wherein the remote plasma source is operative to generate the effluent stream.

11. A particle stream delivery system for use with a semiconductor processing chamber, the system comprising:
a remote plasma source operative to generate an effluent stream of a particle stream containing radicals and a diluent gas;
a plasma generator having an inlet configured to receive the effluent stream and an outlet configured to be coupled to the semiconductor processing chamber, the plasma source operative to generate a glow discharge to excite the radicals and diluent gas in the effluent stream and convey the effluent stream to the semiconductor processing chamber;
a light blocking feature arranged between the remote plasma source and the plasma generator, wherein the light blocking feature is configured to convey the effluent stream but prevent light emitted by the remote plasma source from reaching the plasma generator;
a spectrometer optically coupled to an interior glow discharge region of the plasma source, wherein the spectrometer is operative to output measurement data representing an intensity of light emitted by the radicals and diluent gas; and
a controller communicatively coupled to the spectrometer, the controller operative to calculate a concentration of radicals within the effluent stream based on the measurement data.
